(19) United States
(12) Patent Application Publication
(10) Pub. No.: US 2026/0123338 A1
(43) Pub. Date: Apr. 30, 2026

(54) SUBSTRATE BOW MEASUREMENT AND CONTROL

(71) Applicant: Applied Materials, Inc., Santa Clara, CA (US)

(72) Inventors: Erica de Leon Sanchez, San Francisco, CA (US); Thomas Kirschenheiter, Tempe, AZ (US); Maribel Maldonado-Garcia, Valle de Santiago (MX); Zuoming Zhu, Sunnyvale, CA (US); Abhishek Dube, Fremont, CA (US)

(21) Appl. No.: 19/358,981

(22) Filed: Oct. 15, 2025

Related U.S. Application Data
(60) Provisional application No. 63/712,597, filed on Oct. 28, 2024.

(51) Int. Cl. H01L 21/67

(52) U.S. Cl. CPC H10P 72/0616; H10P 72/0602

(57) ABSTRACT

Embodiments of the present disclosure relate to substrate bow measurement and control. For example, a system may include a memory, and at least one processing device, operatively coupled with the memory, to initiate a process with respect to a substrate, obtain thermal radiation data corresponding to one or more locations on the substrate, determine an amount of bow of the substrate based on the thermal radiation data, and cause at least one corrective action to be performed based on the amount of bow of the substrate. The least one action includes at least one of cause an alert to be generated, or cause at least one process parameter of the process to be changed.

### CROSS-REFERENCE TO RELATED APPLICATION(S)

The present application claims the benefit of U.S. Provisional Application No. 63/712,597, filed on Oct. 28, 2024, the entire contents of which are hereby incorporated by reference herein.

### TECHNICAL FIELD

Embodiments of the present disclosure generally relate to metrology, and more specifically relate to substrate (e.g., wafer) bow measurement and control.

### BACKGROUND

Substrates such as wafers may be processed for a wide variety of applications, including the fabrication of integrated devices and microdevices. One method of processing substrates includes depositing a material, such as a semiconductor material or a conductive material, on an upper surface of the substrate.

A substrate may become bowed because of processes performed on the substrates and/or during execution of processes on the substrate. Bow is a phenomenon seen in electronic device (e.g., semiconductor device) processing in which a substrate (e.g., a wafer) develops a deviation (e.g., curvature and/or distortion) from a flat surface. Bow may impact electronic device quality and yield. For example, bow may result in misalignment in patterned features, increase the likelihood of defects, and thus decrease yield, negatively impact performance of the electronic device, etc. Some causes of bow include stress on the substrate due to differences in material properties (e.g., coefficients of thermal expansion) of materials deposited on the surface of the substrate, temperature gradients due to uneven heating and/or cooling of the substrate during a process, etching processes that result in removal of material from the surface of the substrate that cause imbalances, etc.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the implementations of the disclosure or any scope of the claims. Its sole purpose is to present some concepts of the disclosure in a simplified form as a prelude to the more detailed description that is presented later.

In some embodiments, a system includes a memory, and at least one processing device, operatively coupled with the memory, to initiate a process with respect to a substrate, obtain thermal radiation data corresponding to one or more locations on the substrate, determine an amount of bow of the substrate based on the thermal radiation data, and cause at least one corrective action to be performed based on the amount of bow of the substrate. The least one action includes at least one of cause an alert to be generated, or cause at least one process parameter of the process to be changed.

In some embodiments, a method includes initiating, by at least one processing device, a process with respect to a substrate, obtaining, by the at least one processing device during the process, thermal radiation data corresponding to one or more locations on the substrate, determining, by the at least one processing device, whether the thermal radiation data satisfies a threshold condition, and in response to determining that the thermal radiation data satisfies the threshold condition, causing, by the at least one processing device, at least one corrective action to be performed to address bow of the substrate.

In some embodiments, a system includes a processing chamber including a substrate support assembly, a thermal radiation detector located above the substrate support assembly, and a bow monitoring system including at least one processing device, operatively coupled with a memory, to initiate a process with respect to a substrate on the substrate support assembly, and obtain, from the thermal radiation detector during the process, thermal radiation data based on an intensity of a plurality of thermal radiation signals. Each thermal radiation signal of the plurality of thermal radiation signals corresponds to a respective location of a plurality of locations with respect to an edge region of the substrate, and the thermal radiation detector is configured to rotate to measure thermal radiation at each location of the plurality of locations. The bow monitoring system is further to cause at least one corrective action to be performed based on an amount of bow of the substrate corresponding to the thermal radiation data. The at least one corrective action includes at least one of cause an alert to be generated, or cause at least one process parameter of the process to be changed.

Numerous other features are provided in accordance with these and other aspects of the disclosure. Other features and aspects of the present disclosure will become more fully apparent from the following detailed description, the claims, and the accompanying drawings.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a schematic cross-sectional view of a system for substrate processing, according to some embodiments.

FIGS. 2A-2B are diagrams of cross-sectional views of a substrate undergoing bow, according to some embodiments.

FIG. 3 is a graph illustrating a relationship between thermal radiation and substrate bow, according to some embodiments.

FIGS. 4A-4B are diagrams of an example system for implementing in-situ substrate bow monitoring and control, according to some embodiments.

FIGS. 5A-5B are flowcharts of example methods for implementing in-situ substrate bow monitoring and control, according to some embodiments.

FIG. 6 is a block diagram illustrating an example system architecture, according to certain embodiments.

FIG. 7 is a flow diagram of a method for training a mapping machine learning model, according to certain embodiments.

FIG. 8 depicts a diagrammatic representation of a machine in the example form of a computing device within which a set of instructions, for causing the machine to perform any one or more of the methodologies discussed herein, may be executed.

### DETAILED DESCRIPTION OF EMBODIMENTS

Embodiments of the present disclosure are directed to substrate bow (“bow”) measurement and control, which may be performed, in-situ in a processing chamber. Some deposition processes that may cause bow of a substrate are epitaxial deposition processes. An epitaxial deposition process may be used to deposit epitaxial layers, or epitaxial films, of various materials on a surface of a substrate in a processing chamber. More specifically, an epitaxial layer may be a crystalline layer of material grown on a substrate, where the crystalline material mimics or aligns with the crystal structure of the underlying substrate. Superlattice epitaxy is one type of epitaxial deposition process in which a superlattice is formed on a substrate. Superlattice epitaxy refers to a specialized form of epitaxial growth in which alternating, ultra-thin layers of different materials are deposited to create a periodic structure, known as a superlattice. A goal of superlattice epitaxy is to form a layered material where the individual layers are only a few atoms or molecules thick. The thickness of the individual layers may range from a few atomic monolayers to tens of nanometers. Epitaxial growth may result in epitaxial strain and bow due to material mismatch. Any variation in the shape of a substrate due to bow may impact metrology and downstream integration techniques.

Typical techniques for monitoring substrate bow to improve electronic device quality and yield are performed ex-situ, or outside of a processing chamber where the substrate is being processed. Such ex-situ methods may be performed post-processing, which means bow cannot be addressed during substrate processing. Consequently, these ex-situ methods may not support real-time or near real-time monitoring and/or remediation of bow.

Embodiments described herein address at least the above-noted drawbacks of bow monitoring by providing in-situ substrate bow measurement and control. This approach may enable real-time or near real-time measurement of bow during substrate processing within a processing chamber, facilitating the control of processing parameters to mitigate bow during the process itself. This bow measurement and control may be repeatable from process-to-process. For instance, some embodiments may measure bow during deposition processes, including epitaxial deposition processes like superlattice epitaxy. Further details on these deposition processes will be provided below.

To implement substrate bow measurement and control during substrate processing (e.g., a deposition process), a substrate bow measurement and control system (“system”) may include a thermal radiation detector. This detector may be located above the substrate to measure thermal radiation emitted from an edge region of the substrate and is referred to as a “side detector.” Thermal radiation refers to the electromagnetic radiation emitted by the thermal motion of particles in matter. For example, the side detector may read thermal radiation from the edge region, and its output signal may be converted to temperature based on the emissivity of the edge region (e.g., using the Stefan-Boltzmann equation). Examples of thermal radiation detectors include pyrometers, thermometers, etc.

In some embodiments, the system further includes an additional thermal radiation detector located above the substrate to measure thermal radiation emitted about the center of the substrate, referred to herein as a “center detector.” In some embodiments, at least the side detector is operatively coupled to a rotating motor (e.g., formed on a rotating stage). The side detector may be oriented at an angle relative to the substrate (e.g., not pointed normal to the substrate), with example angles including about 80 degrees to about 89 degrees (e.g., 81, 82, 83, 85, 87, or 88 degrees). The rotating motor may cause movement of the side detector to vary its collection position. During substrate processing, the thermal radiation detector(s) may measure thermal radiation from one or more locations on the substrate. In some embodiments, during a deposition process (e.g., an epitaxial deposition process such as superlattice epitaxy), the thermal radiation detector(s) measure thermal radiation emitted by the layer or film being deposited. For instance, thermal radiation from the edge region of the substrate may be measured by a side detector. Accordingly, a system described herein may include multiple thermal radiation detectors (e.g., a center detector and a side detector) positioned at various locations within a processing chamber above the substrate to measure thermal radiation emitted from multiple locations on the substrate (e.g., within an edge region).

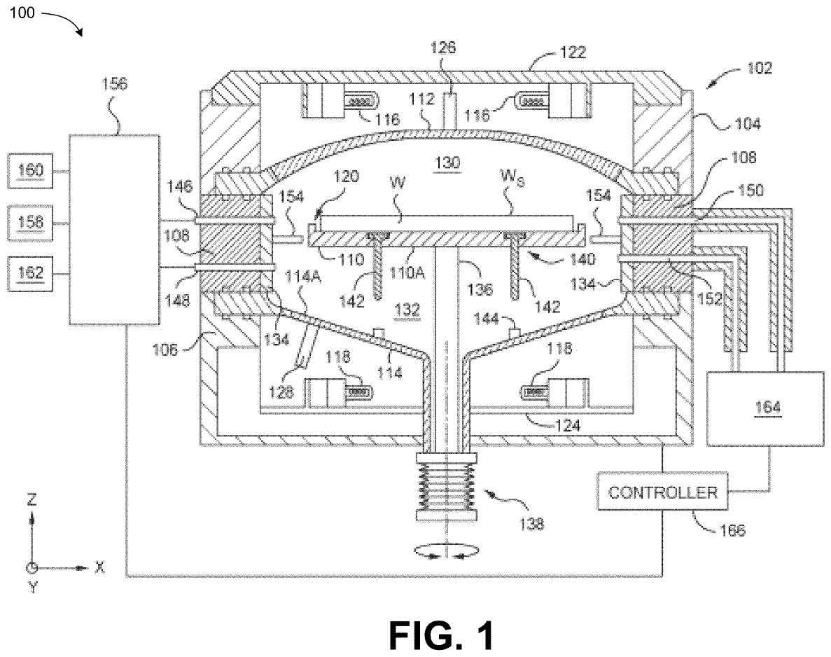

Changes in the thermal radiation emitted from the edge region during deposition may correlate with the amount of bow due to optical absorption. In some embodiments, this correlation is modeled using a mathematical model. In some embodiments, a machine learning model is trained on thermal radiation data and substrate bow data to receive thermal radiation data and output an estimated bow. In other embodiments, the machine learning model is trained to receive thermal radiation data and output updates to process parameter settings or values that will reduce the amount of substrate bow. Accordingly, the thermal radiation data generated by the thermal radiation detector(s) may be provided to a bow monitoring system that is configured to measure and/or control bow based on this data. Further details regarding implementing substrate bow measurement and control will be described below with reference to FIGS. 1-6.

Embodiments of the present disclosure provide various technical advantages. For example, embodiments described herein may measure bow in real-time or near real-time during substrate processing, rather than after processing. This may enable real-time or near real-time control of the substrate processing to reduce or eliminate bow, which may improve electronic device quality and yield.

FIG. 1 is a schematic cross-sectional view of system 100 for substrate processing, according to some embodiments. System 100 includes processing chamber 102. In one or more embodiments, processing chamber 102 is a deposition chamber. In some embodiments, which may be combined with other embodiments, processing chamber 102 is an epitaxial deposition chamber. Processing chamber 102 is utilized to grow an epitaxial film on substrate W. Processing chamber 102 creates a crossflow of precursors across surface Wₛ of substrate W to deposit a film.

Processing chamber 102 includes upper body 104, lower body 106 disposed below upper body 104, and flow module 108 disposed between upper body 104 and lower body 106. Upper body 104, flow module 108, and lower body 106 form a chamber body. Disposed within the chamber body is substrate support 110, upper window 112 (such as an upper dome), lower window 114 (such as a lower dome), upper heat sources 116, and lower heat sources 118.

Substrate support 110 is disposed between upper window 112 and lower window 114. Substrate support 110 includes front surface 120 that faces upper window 112 and supports substrate W. Upper heat sources 116 may be positioned between upper window 112 and lid 122. Lower heat sources 118 may be positioned between lower window 114 and floor 124. Upper window 112 and lower window 114 may be domes formed of an energy transmissive material, such as quartz. In some embodiments, upper heat sources 116 and lower heat sources 118 are lamps. Other heat sources are contemplated, such as resistive heaters, light emitting diodes (LEDs), and/or lasers.

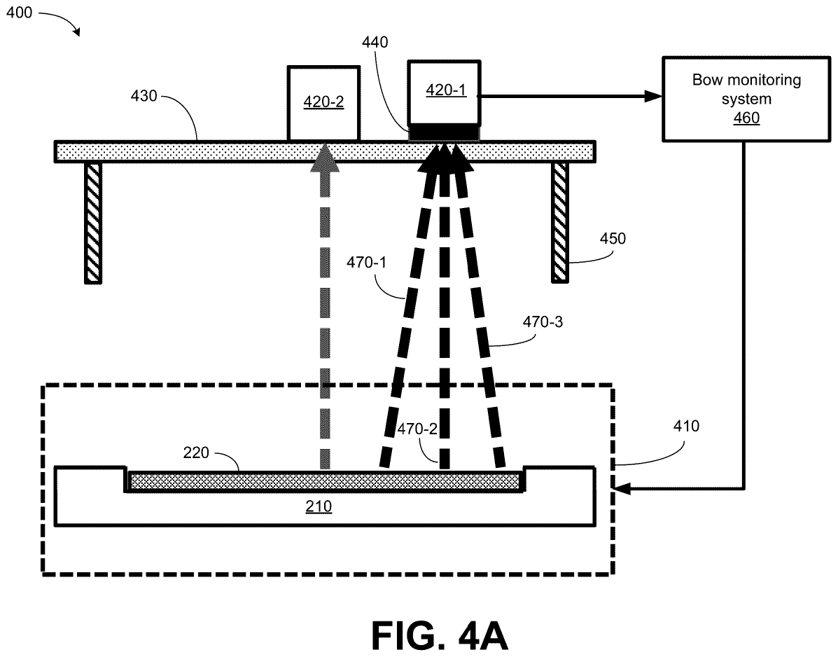

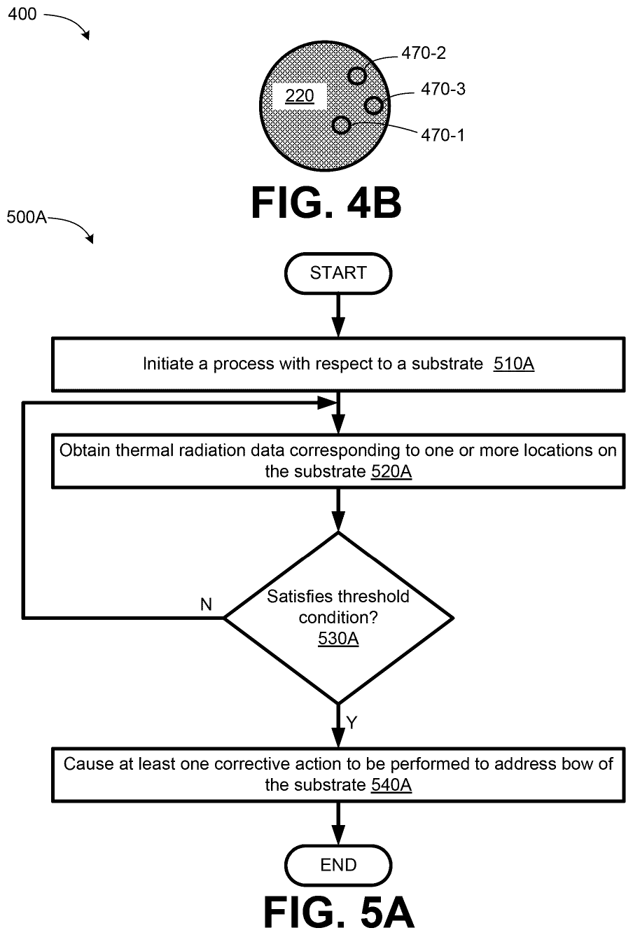

Processing chamber 102 may include thermal radiation detectors (e.g., pyrometers and/or thermometers), which measure thermal radiation and/or temperature within processing chamber 102. For example, the thermal radiation detectors may include one or more thermal radiation detectors 126 on an upper side of upper window 112, and one or more thermal radiation detectors 128 on a lower side of lower window 114. In some embodiments, as will be described in further detail below with reference to FIGS. 4A-4B, thermal radiation detectors 126 include a center detector and a side detector. The center detector may measure thermal radiation emitted from a center region of the substrate, and the side detector may measure thermal radiation emitted from an edge region of the substrate.

Process volume (also referred to as an “upper volume”) 130 and purge volume (also referred to as a “lower volume”) 132 are formed between upper window 112 and lower window 114. Process volume 130 and purge volume 132 are part of an internal volume defined at least partially by upper window 112, lower window 114, and one or more liners 134.

The internal volume has substrate support 110 disposed therein. Purge volume 132 is on the opposite of substrate support 110 from front surface 120 and substrate W disposed thereon. Substrate support 110 is attached to shaft 136. Motion assembly 138 includes one or more actuators and/or adjustment devices that provide movement and/or adjustment for shaft 136 and/or substrate support 110 within processing volume 130.

Substrate support 110 may include lift pin holes 140 disposed therein. Lift pin holes 140 are sized to accommodate lift pin 142 for lowering and/or lifting of substrate W from substrate support 110 before and/or after a deposition process is performed. Lift pins 142 may rest on lift pin stops 144 when substrate support 110 is lowered from a process position to a transfer position.

Flow module 108 includes process inlet passage 146 in fluid communication with process volume 130, and purge inlet passage 148 in fluid communication with purge volume 132. Flow module 108 further includes process outlet passage 150 in fluid communication with process volume 130, and purge outlet passage 152 in fluid communication with purge volume 132. Process inlet passage 146 and purge inlet passage 148 may be positioned on the opposite side of flow module 108 from process outlet passage 150 and purge outlet passage 152. One or more flow guides 154 may be positioned below process inlet passage 146 and process outlet passage 150. These flow guides 154 may also be positioned above purge inlet passage 148. In one or more embodiments, the one or more flow guides 154 include a pre-heat ring. One or more liners 134 may be positioned on an inner surface of flow module 108 and protect flow module 108 from reactive gases used during deposition and/or cleaning operations. Process inlet passage 146 and purge inlet passage 148 may each be positioned to flow a gas parallel to surface Wₛ of substrate W disposed within process volume 130. Process inlet passage 146 and purge inlet passage 148 are fluidly connected to gas supply system 156, which coordinates the gases to be delivered to processing chamber 102. At least one process gas source 158, at least one cleaning gas source 160, and at least one purge gas source 162 may be fluidly connected to gas supply system 156. In some embodiments, the at least one process gas source 158 includes one or more reactive gas sources and one or more carrier gas sources. Process outlet passage 150 and purge outlet passage 152 may be fluidly connected to exhaust pump 164 (e.g., a vacuum pump).

One or more process gases supplied to the gas supply system 156 using the at least one process gas source 158 may include one or more reactive gases (such as silicon (Si), phosphorus (P), and/or germanium (Ge)) and/or one or more carrier gases (such as nitrogen (N₂) and/or hydrogen (H₂)). One or more purge gases supplied using the one or more purge gas sources 162 may include one or more inert gases (such as hydrogen (H₂), argon (Ar), helium (He), and/or nitrogen (N₂)). One or more cleaning gases supplied using the at least one cleaning gas source 160 may include one or more of hydrogen (H₂) and/or chlorine (Cl). In some embodiments, which may be combined with other embodiments, the one or more process gases include silicon phosphide (SiP) and/or phosphine (PH₃), and the one or more cleaning gases include hydrochloric acid (HCl).

As shown, system 100 includes system controller (“controller”) 166 in communication with processing chamber 102. Controller 166 may be used to control processes and methods, such as the operations described herein. Controller 166 may be in communication with exhaust pump 164 and gas supply system 156. Controller 166 may control the gas exhausted from processing chamber 102 using sensors located along exhaust pump 164 and/or gas supply system 156. By monitoring the purity content of the gas, controller 166 may control gas supply system 156 and determine (and control) where gas(es) flow in system 100.

Controller 166 may include a central processing unit (CPU), a memory containing instructions, and support circuits for the CPU. Controller 166 controls various items directly, or via other computers and/or controllers. In one or more embodiments, controller 166 is communicatively coupled to dedicated controllers, and controller 166 functions as a central controller.

Controller 166 may be any form of a general-purpose computer processor used in an industrial setting for controlling various substrate processing chambers, equipment, and sub-processors. The memory, or non-transitory computer readable medium, may be one or more of readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read-only memory (ROM), floppy disk, hard disk, flash drive, or any other form of digital storage, whether local or remote. The support circuits of controller 166 may be coupled to the CPU for supporting the CPU (a processor). These support circuits may include cache, power supplies, clock circuits, input/output circuitry and subsystems, and the like. Operational parameters (e.g., the pressure, purity, or chemical makeup of a recycled gas) and operations may be stored in the memory as a software routine that is executed or invoked to configure controller 166 into a specific purpose controller for the operations of the various systems/chambers/recycling systems/modules described herein. Controller 166 may be configured to conduct any of the operations described herein. The instructions stored on the memory, when executed, may cause one or more of the operations described herein to be conducted. The various operations described herein may be conducted automatically using controller 166, or may be conducted automatically and/or manually with certain operations conducted by a user.

Controller 166 may be configured to adjust output to controls of system 100 based on sensor readings, a system model, and stored readings and calculations. Controller 166 includes embedded software and a compensation algorithm to calibrate measurements. Controller 166 may include one or more machine learning and/or artificial intelligence algorithms that estimate optimized parameters for deposition operation(s), purge operation(s), and/or cleaning operation(s). These algorithms may use, for example, a regression model (such as a linear regression model) or a clustering technique to estimate optimized parameters, and may be unsupervised or supervised.

In some embodiments, gas supply system 156 is responsible for providing all gases to processing chamber 102, regardless of which of the at least one process gas source 158, at least one cleaning gas source 160, or at least one purge gas source 162 supplies the gases. Gas supply system 156 may be controlled by controller 166.

An epitaxial deposition process may be performed to deposit layers on surface Wₛ of substrate W, which may be supported on front surface 120 of substrate support 110 located within process volume 130 of processing chamber 102. This process may include flowing one or more reactive gases from the at least one process gas source 158 into process volume 130 of processing chamber 102. The reactive gases may enter process volume 130 via process inlet passage 146, which may be located above the one or more flow guides 145, and exit via process outlet passage 150.

For example, the deposited layers may be alternating layers of first material (e.g., silicon (Si)) and second material (e.g., silicon germanium (SiGe)). Each layer may have a thickness of between about 50 Å and about 1000 Å. The number of pairs of layers of the first material and the second material is more than 2.

In some embodiments, the one or more reactive gases include a deposition gas and a carrier gas. The deposition gas includes a silicon or germanium-containing precursor and a dopant source. The dopant source may include a precursor phosphine (PH₃), phosphorus trichloride (PCl₃), triisobutylphosphine ([(CH₃)₃C]₃P), arsine (AsH₃), arsenic trichloride (AsCl₃), tertiarybutylarsine (AsC₄H₁₁), antimony trichloride (SbCl₃), or Sb(C₂H₅)₅, including n-type dopants such as phosphorus (P), arsenic (As), or antimony (Sb). The dopant source may include a precursor diborane (B₂H₆), or trimethylgallium (Ga(CH₃))₃, including p-type dopants such as boron (B) or gallium (Ga). The carrier gas may include nitrogen (N₂), argon (Ar), helium (He), or hydrogen (H₂).

During the epitaxial deposition process, a portion of the deposition gas may leak into purge volume 132 (located between flow guide 154 and substrate support 110) and form a coating on inner surfaces of purge volume 132 (e.g., back surface 110A of substrate support 110 and inner surface 114A of lower window 114, as shown in FIG. 1). Since the epitaxial deposition process may be long (e.g., deposition of 100 pairs of Si and SiGe layers), this coating may accumulate. Such accumulation can cause inaccurate temperature measurement by thermal radiation detector 128 (e.g., a bottom pyrometer) located on lower window 114.

A coating removal process may be performed to reduce or eliminate the coating on the inner surfaces of purge volume 132 (e.g., back surface 110A of substrate support 110 and inner surface 114A of lower window 114). This process may involve flowing purge gas from the at least one purge gas source 162 or cleaning gas from the at least one cleaning gas source 160 through purge volume 132 of processing chamber 102, via purge inlet passage 148 and purge outlet passage 152. The purge gas may include hydrogen (H₂) at a flow rate of more than 2 standard liters per minute (slm), and can dilute the portion of the deposition gas flowed into purge volume 132, which may prevent coating formation on back surface 110A of substrate support 110 and inner surface 114A of lower window 114. The cleaning gas may include a chlorine-containing etchant gas, which may remove existing coating on these surfaces. The purge gas or cleaning gas may be prevented from leaking into process volume 130, which may interfere with the epitaxial deposition process, because they may flow through purge volume 132 via purge inlet passage 148 and purge outlet passage 152, located below flow guides 154.

A temperature monitoring process may be performed to measure the temperature of the inner surface of purge volume 132 (e.g., lower window 114) using thermal radiation detector 128 (e.g., a bottom pyrometer) disposed on lower window 114. The temperature measured at back surface 110A of substrate support 110, which may be on the opposite side of substrate support 110 from substrate W disposed thereon, may not be affected by growth of a film on substrate W. This measured temperature may not be affected by a coating on back surface 110A of substrate support 110 or on inner surface 114A of lower window 114, as the coating may be reduced or eliminated using the coating removal process described above.

A temperature control process may be performed to adjust the temperature at the inner surface of purge volume 132 (e.g., lower window 114). This adjustment may be based on the temperature measured at the inner surface of purge volume 132 (e.g., lower window 114), specifically on the opposite side of substrate support 110 from substrate W. Adjustments are made by varying power provided to upper heat sources 116 and lower heat sources 118. Various gas flow rates may also be adjusted to control the temperature at lower window 114.

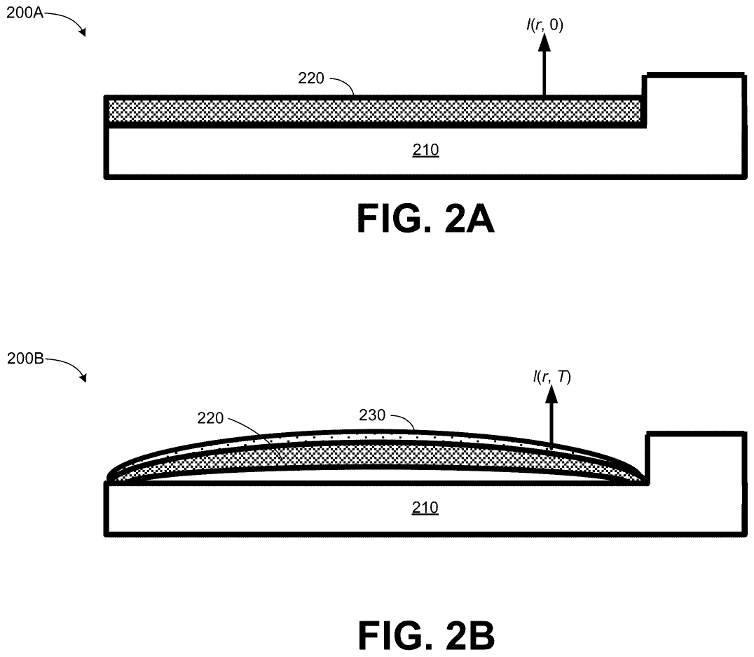

In some embodiments, controller 166 may receive thermal radiation data from one or more of thermal radiation detectors 126, 128 (e.g., the side detector). It may then process this data to determine whether an amount of thermal radiation satisfies a threshold condition. If the threshold condition is satisfied, the controller may cause at least one corrective action to be performed to address bow of the substrate (e.g., generates an alert and/or adjusts process parameters). Further details regarding these embodiments will now be described below with reference to FIGS. 2A-5.

FIG. 2A is a diagram 200A of a cross-sectional view of a substrate (e.g., a wafer) 220 on substrate support assembly or apparatus 210 during a deposition process at an initial time t=0, according to some embodiments. For example, substrate support assembly 210 may include a susceptor. The edge region of substrate 220 may be defined by a distance from the center of substrate 220, referred to as r. For example, if substrate 220 includes a circular wafer, then the distance from the center of substrate 220 may correspond to a radial distance from the center of the substrate 220. In some embodiments, the amount of thermal radiation emitted from the edge region of substrate 220 is determined with respect to a current deposition time t. Mathematically, the amount of thermal radiation at distance r and time t may be represented by I(r, t). In some embodiments, the amount of thermal radiation is an intensity of the thermal radiation. In FIG. 2A, which shows the deposition process at time t=0, the amount of thermal radiation at the distance r is represented by I(r, 0).

FIG. 2B is a diagram 200B of a cross-sectional view of substrate 220 during the deposition process at a subsequent time t=T after the initial time t=0, according to some embodiments. As shown in FIG. 2B, material 230 (e.g., film) has been formed on substrate 220 at time T of the deposition process. As further shown in FIG. 2B, the amount of thermal radiation at the distance r and time T is represented by I(r, T). As further shown in 2BG. 2B, substrate 220 has undergone bowing as a result of the deposition process. The amount of bowing of the substrate 220 at time T may be proportional to ΔI_{T}, which is the change in the amount of thermal radiation from time t=0 to time t=T. Mathematically, this may be represented by B(T)∝ΔI_{T}=I(r, T)−I(r, 0), where B(T) is the amount of bowing of the substrate 220 at time T.

In some embodiments, the deposition process is an epitaxial deposition process and material 230 is formed by epitaxially growing layers of material 230. For example, the epitaxial deposition process may be superlattice epitaxy, and material 230 may be formed by epitaxially growing superlattice layers. In these embodiments, the amount of thermal radiation emitted from the edge region of substrate 220 may be determined with respect to a current layer of material 230 that has been deposited via epitaxial deposition. That is, the current layer of material 230 may serve as a proxy for deposition time. Mathematically, the amount of thermal radiation at distance r and layer n may be represented by I(r, n). It is assumed that n=0 at the initial time t=0, and that n=N at time t=T. The amount of bowing at time T may be proportional to ΔI_{N}, which is the change in the amount of thermal radiation from n=0 to n=N. Mathematically, this may be represented by B(N)∝ΔI_{N}=I(r, N)−I(r, 0), where B(N) is the amount of bowing of the substrate 220 with respect to the formation of layer N. Accordingly, the amount of bowing of substrate 220 may be measured with respect to deposition time, a number of layers formed within the deposition time, etc.

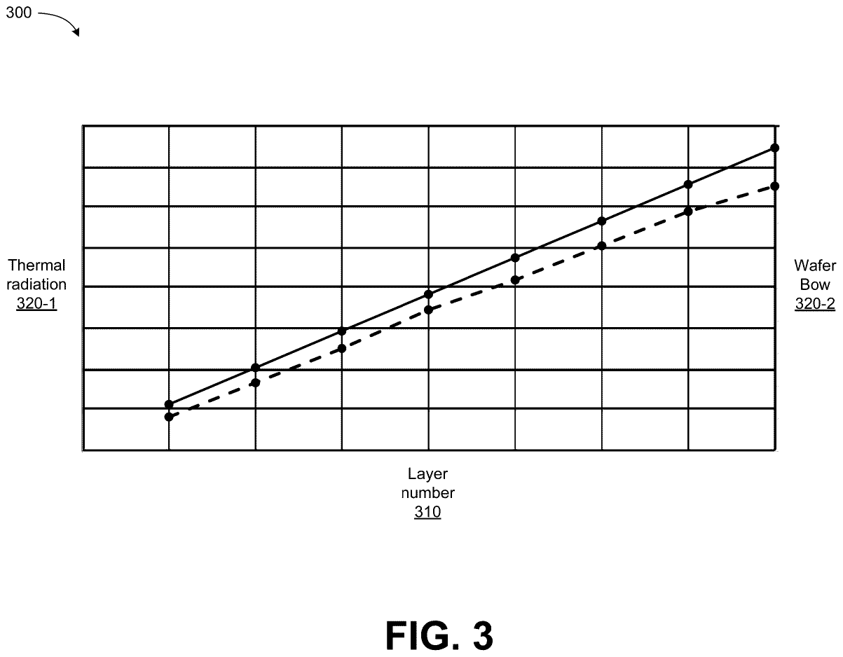

FIG. 3 is a graph 300 illustrating a relationship between thermal radiation and bow, according to some embodiments. Graph 300 includes x-axis 310 representing a deposition metric corresponding to the deposition process being performed with respect to a substrate within a processing chamber. For example, the deposition metric may be deposition time or a layer number, as described above with reference to FIGS. 2A-2B. Graph 300 may include multiple y-axes 320-1 and 320-2. The y-axis 320-1 represents an amount of thermal radiation, and the y-axis 320-2 represents an amount of bow of the substrate (e.g., in millimeters (mm)). More specifically, the solid line of graph 300 may represent the amount of thermal radiation emitted from an edge region of the substrate as a function of the deposition metric, and the dashed line of graph 300 may represent the amount of bow of the substrate. As may be seen in FIG. 3, the amount of thermal radiation and the amount of bow of the substrate have a direct relationship as a function of the deposition metric.

Mathematical analysis techniques (e.g., statistical analysis techniques) may determine a model or function representing the relationship between thermal radiation and bow. This model may be derived from experimental results. The relationship may be unique to the process type and its controlling process parameters.

A mathematical model (e.g., an equation) may be used to relate thermal radiation and bow to at least one of layer number or time. Thermal radiation and layer number/time values may be input into this model to determine real-time bow. In some embodiments, the mathematical model is established using regression analysis of individual sub-models. For instance, one sub-model could relate layer number/time to bow, and another could relate layer number/time to thermal radiation. These individual sub-models may be derived from experimental results of ex-situ bow measurements at different layer numbers and/or times.

FIG. 4A illustrates system 400 for implementing in-situ bow monitoring and control. System 400 may include processing chamber 410, similar to processing chamber 102 of FIG. 1, which houses substrate support assembly 210 and substrate 220 (e.g., a wafer). Processing chamber 410 may perform a deposition process to deposit material on substrate 220. In some embodiments, the deposition process is an epitaxial deposition process, such as superlattice epitaxy, which is performed to grow material epitaxially on the substrate.

System 400 also includes thermal radiation detector 420-1, referred to as a “side detector,” positioned above substrate 220 to measure thermal radiation emitted from its edge. Thermal radiation detector 420-1 may be a pyrometer, a thermometer, etc., and may be oriented at an angle relative to substrate 220.

In some embodiments, as shown in FIG. 4A, system 400 further includes thermal radiation detector 420-2, such as another pyrometer, thermometer, etc., located above the center of substrate 220 to measure thermal radiation emitted from that region. Thermal radiation detector 420-2 is referred to as a “center detector.” Thus, system 400 may incorporate multiple thermal radiation detectors at various positions above substrate 220.

Thermal radiation detector 420-1 (and thermal radiation detector 420-2) may be mounted on a first side of mounting plate 430. In some embodiments, system 400 may also include reflectors formed on the opposite side of mounting plate 430 to reflect thermal radiation emitted from substrate 220.

During processing of substrate 220, at least thermal radiation detector 420-1 may measure thermal radiation. In some embodiments, during a deposition process (e.g., superlattice epitaxy), at least thermal radiation detector 420-1 measures thermal radiation emitted by the film being deposited on substrate 220 from its edge region. As discussed above, changes in thermal radiation from the edge of substrate 220 during deposition may correlate with bow due to optical absorption. The thermal radiation data from the detector(s) may be provided to bow monitoring system 460, configured to measure and/or control bow of the substrate based on this data. In some embodiments, bow monitoring system 460 is implemented by a controller, such as controller 166 of FIG. 1.

In some embodiments, thermal radiation detector 420-1 receives at least one thermal radiation signal from substrate 220 (e.g., from its edge region), and bow monitoring system 460 measures and/or controls the bow of the substrate 220 using the at least one thermal radiation signal.

In some embodiments, thermal radiation detector 420-1 receives multiple thermal radiation signals from substrate 220, and bow monitoring system 460 measures and/or controls the bow of the substrate 220 using the multiple thermal radiation signals. For instance, bow monitoring system 460 may base its bow measurement and/or control on an average of the thermal radiation amounts determined from the multiple thermal radiation signals.

For example, as shown in FIG. 4A, thermal radiation detector 420-1 may receive multiple signals, including signal 470-1, signal 470-2, and signal 470-3. Signal 470-1 may correspond to an amount of thermal radiation (e.g., signal intensity) at a first radial distance from the center of substrate 220. Signal 470-2 may correspond to an amount of thermal radiation at a second radial distance, farther from the center of substrate 220 than the first radial distance (e.g., closer to the edge of substrate 220). Signal 470-3 may correspond to an amount of thermal radiation at a third radial distance, farther from the center of substrate 220 than the second radial distance (e.g., even closer to the edge of substrate 220). In some embodiments, thermal radiation detector 420-1 moves (e.g., rotates) to adjust the measured locations on the substrate. Alternatively, additional thermal radiation detectors (not shown) may be fixed above substrate 220 and pointed to different locations. FIG. 4B is a top-down view of example locations on substrate 220 from which the signals may be obtained.

Referring back to FIG. 4A, in some embodiments, at least thermal radiation detector 420-1 is operatively coupled to rotating motor 440 (e.g., formed on a rotating stage). Rotating motor 440 may cause movement of thermal radiation detector 420-1 to vary its collection position (e.g., to capture the signals at various distances from the center of substrate 220). In some embodiments, bow monitoring system 460 controls the operation of rotating motor 440. Rotating motor 440 may rotate thermal radiation detector 420-1 about a vertical axis or an axis normal to the plane of the image of FIG. 4A.

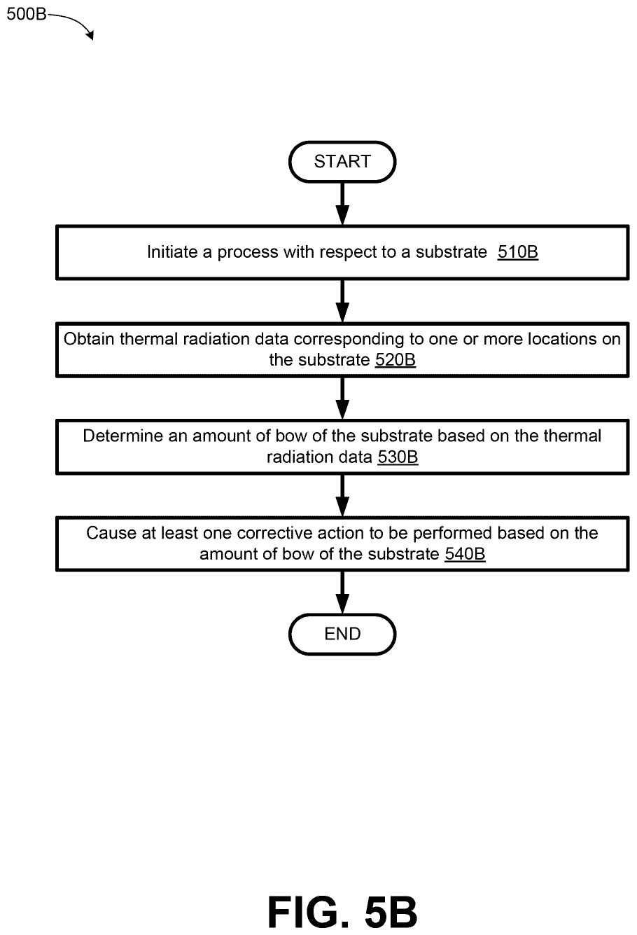

In some embodiments, bow monitoring system 460 determines whether the thermal radiation satisfies a threshold condition (e.g., if the change in the amount of thermal radiation is greater than or exceeds a target amount). If so, bow monitoring system 460 may cause at least one corrective action to be performed to address substrate bow. This may involve generating an alert for a user device, indicating sufficiently high thermal radiation, which suggests bow may have occurred or may be imminent unless further corrective action is taken. Additionally, or alternatively, causing the at least one corrective action to be performed may include automatically controlling processing of substrate 220 by changing at least one process parameter (e.g., temperature, pressure, process duration, flow) to ensure the change in the amount of thermal radiation may be less than or equal to the target amount. Illustratively, for an epitaxial deposition process forming SiGe layers, bow may be related to film strain from atom incorporation (e.g., Ge atoms). If substrate bow is deemed too high based on the amount of thermal radiation (e.g., the change in the amount of thermal radiation), examples of changing process parameters include reducing precursor flow (e.g., Ge precursor flow) or shortening layer deposition time (e.g., SiGe layer). Further details are described below with reference to FIG. 5A.

In some embodiments, bow monitoring system 460 determines the amount of substrate bow based on the thermal radiation data and causes the at least one corrective action to be performed based on the amount of substrate bow (e.g., generating an alert and/or changing process parameters). For instance, it may determine if the substrate bow amount satisfies a threshold condition (e.g., if it exceeds a target amount) and perform the corrective action if the condition is met. In certain embodiments, bow monitoring system 460 inputs the thermal radiation data into a machine learning model trained to determine the bow amount and/or trigger corrective actions. Further details are described below with reference to FIG. 5B.

FIG. 5A is a flowchart of method 500A for implementing in-situ bow monitoring and control, according to some embodiments. Method 500A is performed by a system that may include hardware (circuitry, dedicated logic, optical measuring tools as described herein, etc.), software (such as is run on a general-purpose computer system or a dedicated machine), firmware, or some combination thereof. In some embodiments, method 500A is performed by a system controller, such controller 166 of FIG. 1 and/or bow monitoring system 460 of FIG. 4. In other or similar implementations, one or more operations of method 500A may be performed by one or more other machines not depicted in the figures.

At operation 510A, processing logic initiates a process with respect to a substrate. This process may be a deposition process to deposit material on the substrate. In some embodiments, the deposition process includes an epitaxial deposition process, such as superlattice epitaxy.

At operation 520A, processing logic obtains thermal radiation data corresponding to one or more locations on the substrate. The thermal radiation data may be obtained during the deposition process (e.g., in-situ) and may indicate the amount of thermal radiation emitted from an edge region of the substrate. The thermal radiation data may be obtained based on at least one or multiple thermal radiation signals (e.g., their intensity), where each thermal radiation signal may correspond to a respective substrate location. For example, the thermal radiation data may be generated using an average intensity of multiple thermal radiation signals. In some embodiments, the thermal radiation data includes a change in thermal radiation intensity between a first thermal radiation signal from a given location at an initial process state (e.g., initial time or zero-layer state) and a second thermal radiation signal from the same location at a current process state (e.g., current time or current-layer state).

At operation 530A, processing logic determines whether the thermal radiation data satisfies a threshold condition. This may include determining whether an amount of thermal radiation, or a change in the amount of thermal radiation, indicated by the thermal radiation data is greater than or equal to a target amount. If the thermal radiation does not satisfy the threshold condition, it indicates sufficiently small substrate bow, requiring no corrective action. The process may then revert to operation 520A to continue receiving thermal radiation data.

Otherwise, if the thermal radiation satisfies the threshold condition (e.g., the amount of thermal radiation or the change in the amount of thermal radiation is greater than the target amount), processing logic at operation 540A causes at least one corrective action to be performed to address substrate bow. This may include generating an alert sent to a user device, indicating sufficiently high thermal radiation, which suggests bow may have occurred or may be imminent unless further corrective action is taken. Additionally, or alternatively, it may involve automatically controlling substrate processing by changing at least one process parameter (e.g., temperature, pressure, process duration, flow) to ensure the change in thermal radiation is less than or equal to the target amount. For an epitaxial deposition process forming layers (e.g., SiGe layers), bow is related to film strain from atom incorporation (e.g., Ge atoms). If substrate bow is deemed too high based on the thermal radiation data, examples of changing process parameters include reducing precursor flow (e.g., Ge precursor flow) and/or shortening layer deposition time (e.g., SiGe layer). Further details regarding operations 510A-540A are described above with reference to FIGS. 2A-4B and will be described in further detail below with reference to FIGS. 5B-7.

FIG. 5B is a flowchart of method 500B for implementing substrate bow monitoring and control, according to some embodiments. Method 500B is performed by a system that may include hardware (circuitry, dedicated logic, optical measuring tools as described herein, etc.), software (such as is run on a general-purpose computer system or a dedicated machine), firmware, or some combination thereof. In some embodiments, method 500B is performed by a system controller, such controller 166 of FIG. 1 and/or bow monitoring system 460 of FIG. 4. In other or similar implementations, one or more operations of method 500B may be performed by one or more other machines not depicted in the figures.

At operation 510B, processing logic initiates a process with respect to a substrate. This process may be a deposition process to deposit material on the substrate. In some embodiments, the deposition process includes an epitaxial deposition process, such as superlattice epitaxy.

At operation 520B, processing logic obtains thermal radiation data corresponding to one or more locations on the substrate. The thermal radiation data may be obtained during the deposition process (e.g., in-situ) and may indicate the amount of thermal radiation emitted from an edge region of the substrate. The thermal radiation data may be obtained based on at least one or multiple thermal radiation signals (e.g., their intensity), where each thermal radiation signal may correspond to a respective substrate location. For example, the thermal radiation data may be generated using an average intensity of multiple thermal radiation signals. In some embodiments, the thermal radiation data includes a change in thermal radiation intensity between a first thermal radiation signal from a given location at an initial process state (e.g., initial time or zero-layer state) and a second thermal radiation signal from the same location at a current process state (e.g., current time or current-layer state).

At operation 530B, processing logic determines an amount of bow of the substrate based on the thermal radiation data. This may include inputting the thermal radiation data into a machine learning model trained to determine the amount of bow from the thermal radiation data.

At operation 540B, processing logic causes at least one corrective action to be performed based on the amount of substrate bow. This may include generating an alert sent to a user device, indicating sufficiently high thermal radiation, which suggests bow may have occurred or may be imminent unless further corrective action is taken. Additionally, or alternatively, it may involve automatically controlling substrate processing by changing at least one process parameter (e.g., temperature, pressure, process duration, flow) to ensure the change in thermal radiation is less than or equal to the target amount. For an epitaxial deposition process forming layers (e.g., SiGe layers), bow is related to film strain from atom incorporation (e.g., Ge atoms). If substrate bow is deemed too high based on the thermal radiation data, examples of changing process parameters include reducing precursor flow (e.g., Ge precursor flow) and/or shortening layer deposition time (e.g., SiGe layer).

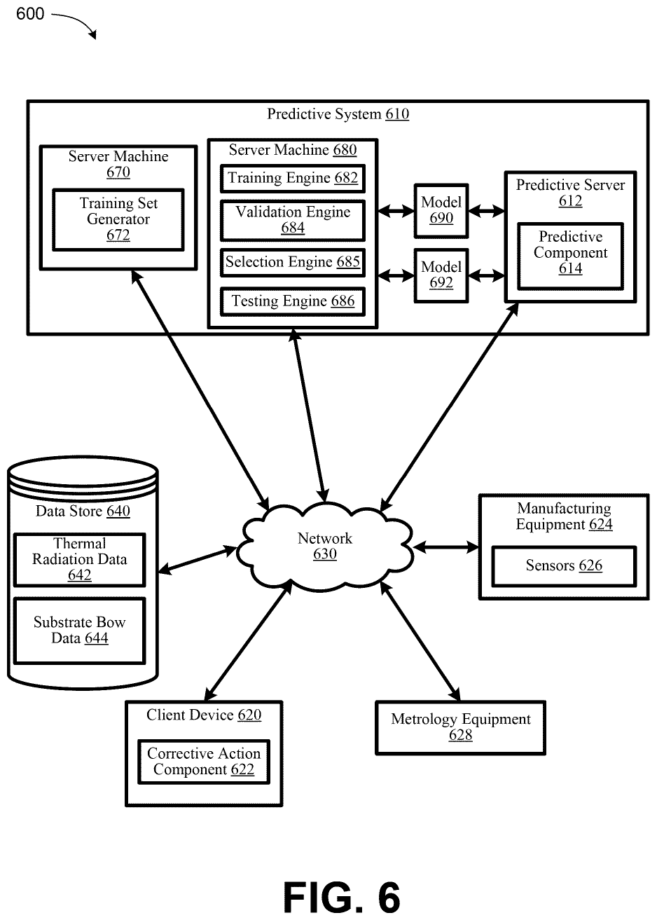

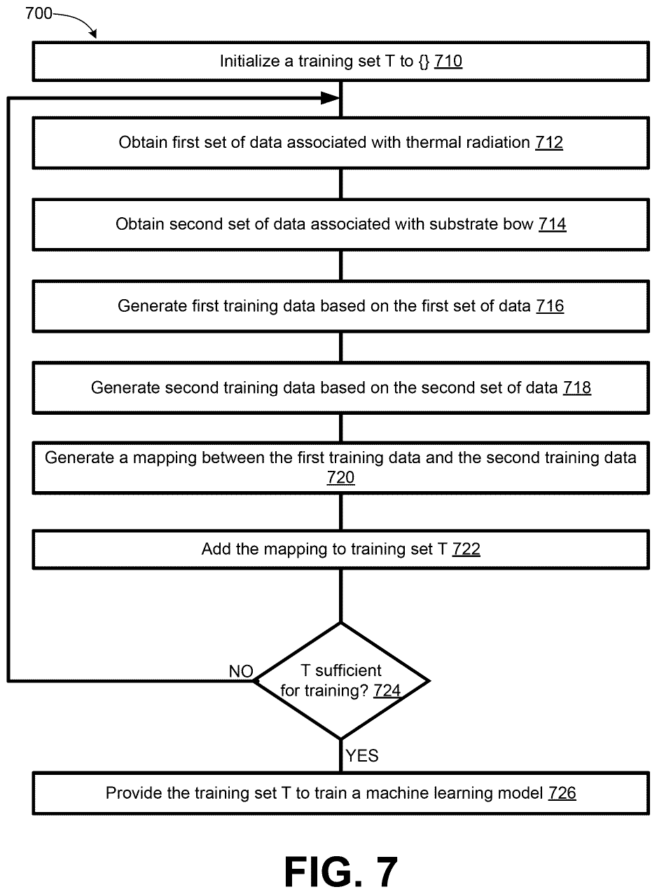

In some embodiments, processing logic determines whether the amount of bow of the substrate satisfies a threshold condition and performs the corrective action in response to this determination. For example, this determination may involve checking if the amount of bow is greater than or equal to a target amount. Conversely, if the bow amount does not satisfy the threshold (e.g., it is less than or equal to the target amount), it signifies a sufficiently small bow, requiring no corrective action. In some embodiments, initiating the corrective action includes inputting the thermal radiation data and/or the amount of bow into a machine learning model trained to trigger the action based on this data. Further details regarding operations 510B-540B are described above with reference to FIGS. 2A-5A and will be described in further detail below with reference to FIGS. 6-7.

FIG. 6 depicts computer system architecture 600, according to some embodiments. Computer system architecture 600 may be part of a manufacturing system for processing substrates, such as system 100 of FIG. 1. Computer system architecture 600 includes client device 620, manufacturing equipment 624, metrology equipment 628, predictive server 612 (e.g., to generate predictive data, provide model adaptation, use a knowledge base), and data store 640. Predictive server 612 may be part of predictive system 610, which may also include server machines 670 and 680. Manufacturing equipment 624 may include sensors 626 configured to capture data for a substrate being processed. In some embodiments, manufacturing equipment 624 and sensors 626 form part of a sensor system (e.g., with a sensor server like a field service server (FSS) and sensor identifier reader like a front opening unified pod (FOUP) radio frequency identification (RFID) reader). Metrology equipment 628 may similarly be part of a metrology system (e.g., with a metrology server and metrology identifier reader).

Manufacturing equipment 624 produces products, such as electronic devices, by following a recipe or performing runs over time. Manufacturing equipment 624 may include a processing chamber, similar to processing chamber 102 of FIG. 1, to perform substrate processes (e.g., wafer processing). Examples include deposition processes for film layers and etch processes for surface patterns. Each process is performed according to a process recipe, which defines operations and associated settings. For example, a deposition process recipe may include settings for processing chamber temperature, pressure, precursor flow rate, etc.

In some embodiments, manufacturing equipment 624 includes sensors 626 configured to generate data associated with a substrate processed at manufacturing system 100. For example, a processing chamber may include sensors to generate spectral or non-spectral data for the substrate before, during, and/or after a process (e.g., deposition). Spectral data from sensors 626 may indicate material concentration on a substrate surface. For example, spectral data may be generated by reflectometry, ellipsometry, thermal spectra, or capacitive sensors, and non-spectral data may be generated by temperature, pressure, flow rate, or voltage sensors. Further details regarding the manufacturing equipment 624 are provided above with respect to FIG. 1 and FIGS. 4A-4B.

In some embodiments, sensors 626 provide sensor data (e.g., values, features, trace data) associated with manufacturing equipment 624, specifically regarding product manufacturing (e.g., wafers). Manufacturing equipment 624 produces products based on a recipe or runs over a period. Sensor data received over time (e.g., corresponding to a recipe or run) may be referred to as trace data (historical or current). Sensor data may include values for temperature (e.g., heater temperature), spacing (SP), pressure, high frequency radio frequency (HFRF), electrostatic chuck (ESC) voltage, electrical current, material flow, power, etc. This data may be associated with or indicative of manufacturing parameters, such as hardware parameters (e.g., size, type of components) or process parameters. Sensor data may be provided while the manufacturing equipment 624 performs manufacturing processes (e.g., equipment readings during product processing) and may vary for each substrate.

Metrology equipment 628 may provide metrology data associated with substrates processed by manufacturing equipment 624. This data may include film property data (e.g., wafer spatial film properties), dimensions (e.g., thickness, height), dielectric constant, dopant concentration, density, and defects. In some embodiments, metrology data also includes surface profile property data (e.g., etch rate, etch rate uniformity, critical dimension of features, critical dimension uniformity, edge placement error). Metrology data pertains to finished or semi-finished products and may vary for each substrate. Metrology data may be generated using techniques such as reflectometry, ellipsometry, TEM, etc. Reflectometry techniques include time-domain reflectometry (TDR), frequency-domain reflectometry (FDR), and ellipsometry. TDR emits a series of fast pulses and analyzes the magnitude, duration, and shape of reflected pulses. FDR is based on transmitting stepped-frequency sine waves from the sample, focusing signal analysis on changes in frequency between incident and reflected signals. Ellipsometry includes polarization-resolved measurement of light reflections from films. The reflectometry techniques may obtain sensor data (e.g., reflectance values), which may be processed to generate metrology data.

In some embodiments, metrology equipment 628 is integrated as part of manufacturing equipment 624. For example, metrology equipment 628 may be inside or coupled to a processing chamber, configured to generate metrology data for a substrate before, during, and/or after a process (e.g., deposition, etch) while the substrate remains in the chamber. In such instances, metrology equipment 628 may be referred to as in-situ metrology equipment. Alternatively, metrology equipment 628 may be coupled to another station of manufacturing equipment 624, such as a transfer chamber, a load lock, or a factory interface.

Client device 620 may be a computing device such as personal computer (PC), laptop, mobile phone, smart phone, tablet, netbook, network-connected television, media player, set-top box, over-the-top (OTT) streaming device, operator boxes, etc. In some embodiments, the metrology data is received from client device 620, which may display a graphical user interface (GUI) enabling users to input metrology measurement values for processed substrates. Client device 620 may include corrective action component 622, which receives user input (e.g., via the GUI) indicating an issue with manufacturing equipment 624. In some embodiments, corrective action component 622 transmits this indication to predictive system 610, receives output (e.g., predictive data), determines a corrective action based on the output, and causes its implementation. Alternatively, it may receive a corrective action directly from predictive system 610 and cause its implementation. Client device 620 may include an operating system allowing a user to generate, view, or edit data related to manufacturing equipment indications and corrective actions.

Data store 640 may be a memory (e.g., random access memory), a drive (e.g., hard drive, flash drive), a database system, or any component capable of storing data. Data store 640 may include multiple storage components (e.g., drives or databases) spanning multiple computing devices (e.g., server computers).

Data store 640 may store data associated with processing a substrate at manufacturing equipment 624. This includes sensor data collected by sensors 626 (e.g., thermal detectors) before, during, or after a substrate process, referred to as process data. Process data may be historical (from prior substrates) and/or current (from a current substrate). In some embodiments, the sensor data includes thermal radiation data measured by thermal detectors.

In some embodiments, data store 640 stores spectral data or non-spectral data associated with a portion of a substrate processed at manufacturing equipment 624. Spectral data may include historical and/or current spectral data.

In some embodiments, data store 640 stores contextual data associated with one or more substrates processed at the manufacturing system. Contextual data may include recipe name, recipe step number, preventive maintenance indicator, or operator. This data may be historical (from a prior process for a prior substrate) and/or current (from a current or future process). Contextual data may also identify sensors associated with a particular sub-system of a processing chamber.

In some embodiments, data store 640 stores task data, which may include operations and settings for a substrate during a deposition process. For example, task data for deposition may include temperature, pressure, and flow rate settings for a processing chamber or a precursor. In another example, task data may involve controlling pressure at a defined point for a flow value. Task data may be historical (from a prior process for a prior substrate) and/or current (from a current or future process).

In some embodiments, data store 640 stores film thickness data (e.g., a film thickness profile) associated with one or more film layers. A film thickness profile refers to a particular thickness gradient of deposited film (e.g., changes in thickness along a deposited film layer). This profile may include thickness values for a film stack (e.g., multiple layers of one or more materials) deposited on a substrate surface, as determined by metrology inspection or prediction using a physics engine. Examples of film stacks include an oxide/nitride (ONON) stack, an oxide/polysilicon (OPOP) stack, an aggregated stack (e.g., an aggregated oxide, nitride, or polysilicon stack), or any film stack generated by manufacturing equipment 624 or a simulation model. An aggregated stack may contain thickness data solely for a single material's layers from a multi-material film stack (e.g., an aggregated oxide stack from an ONON stack).

In some embodiments, data store 640 stores expected and correction profiles. An expected profile may include data points associated with a desired film profile anticipated from a specific process recipe, such as the target film thickness. A correction profile may include adjustments or offsets to be applied to processing chamber parameters or the process recipe (e.g., temperature, pressure, precursor flow rate, power, or ratios of settings). It is generated by comparing an expected profile with the actual outcome, and using a library of known fault patterns and/or an algorithm to determine necessary adjustments to achieve the expected profile. The correction profile may be applied to steps within deposition processes, etch processes, etc.

In some embodiments, data store 640 may store data inaccessible to a user of the manufacturing system. For example, process data, spectral data, or contextual data obtained for a processed substrate may be inaccessible to an operator. In certain embodiments, all data in data store 640 may be inaccessible. In other embodiments, a portion of the data is to be inaccessible while another portion is accessible. Data stored at data store 640 may be encrypted using an encryption mechanism unknown to the user (e.g., a private encryption key). Alternatively, data store 640 may include multiple data stores, where inaccessible data may be stored in a first data store and accessible data may be stored in a second data store.

In some embodiments, data store 640 stores data associated with known fault patterns. A fault pattern may include one or more values (e.g., vector, scalar) associated with issues or failures in a processing chamber sub-system. A fault pattern may be linked to a corrective action, such as parameter adjustment steps to resolve the indicated issue or failure.

For example, predictive system 610 may compare a determined fault pattern to a library of known fault patterns to identify the type and cause of failure and recommend corrective actions. In some embodiments, predictive system 610 includes predictive server 612, server machine 670, and server machine 680. Each of these components may include one or more computing devices such as a rackmount server, router computer, server computer, personal computer, mainframe computer, laptop, tablet, desktop, Graphics Processing Unit (GPU), or accelerator Application-Specific Integrated Circuit (ASIC) (e.g., Tensor Processing Unit (TPU)).

Server machine 670 includes a training data set generator 672, capable of generating training data sets (e.g., data inputs and target outputs) to train, validate, and/or test one of trained machine learning models 690, 692. These models may be any algorithmic model capable of learning from data. In some embodiments, trained machine learning model 690 is a mapping model, and trained machine learning model 692 is a predictive model. Some operations of training data set generator 672 are described in detail below with respect to FIG. 7. In some embodiments, training data set generator 672 may partition training data into training, validation, and testing sets, and predictive system 610 may generate multiple sets of training data.

Server machine 680 may include a training engine 682, a validation engine 684, a selection engine 685, and/or a testing engine 686. An engine may refer to hardware (e.g., circuitry, dedicated logic, programmable logic, microcode, processing device, etc.), software (such as instructions run on a processing device, a general-purpose computer system, or a dedicated machine), firmware, microcode, or a combination thereof. Training engine 682 may be capable of training one or more trained machine learning models 690, 692. These models may be artifacts created by training engine 682 using training data (training set) that includes training inputs and corresponding target outputs. Training engine 682 may identify patterns in the training data that map inputs to target outputs, providing trained machine learning models 690, 692 that capture these patterns. Trained machine learning models 690, 692 may utilize statistical modeling, support vector machines (SVM), Radial Basis Function (RBF), clustering, supervised, semi-supervised, or unsupervised machine learning, k-nearest neighbor (k-NN), linear regression, random forest, or neural networks (e.g., artificial neural networks).

Artificial neural networks, such as deep neural networks, are a type of machine learning model that may be used to perform some or all the above tasks. They may include a feature representation component with classifier or regression layers that map features to a desired output space. A convolutional neural network (CNN), for example, uses multiple layers of convolutional filters, performing pooling and addressing non-linearities at lower layers. A multi-layer perceptron is commonly appended on top, mapping features extracted by convolutional layers to decisions (e.g., classification outputs). Deep learning is a class of machine learning algorithms that use a cascade of multiple layers of nonlinear processing units for feature extraction and transformation, where each successive layer uses the output from the previous layer as input. Deep neural networks can learn in a supervised (e.g., classification) and/or unsupervised (e.g., pattern analysis) manner, forming a hierarchy of layers where different levels of representations correspond to different levels of abstraction. Each level learns to transform its input data into a slightly more abstract and composite representation. In plasma process tuning, for example, raw input could include process result profiles (e.g., thickness profiles). The second layer may include feature data on controlled elements of a plasma process system (e.g., zone orientation, plasma exposure), and the third layer may include a starting recipe for an updated process. Notably, deep learning processes can autonomously learn optimal feature placement. The term “deep” in deep learning refers to the number of layers transforming data. More precisely, deep learning systems have substantial credit assignment path (CAP) depth, which is the chain of transformations from input to output, describing potential causal connections. For a feedforward neural network, CAP depth equals network depth (number of hidden layers plus one).

In some embodiments, a machine learning model is a recurrent neural network (RNN). An RNN is a type of neural network with memory, enabling it to capture temporal dependencies. An RNN learns input-output mappings that depend on current and past inputs, addressing past and future flow rate measurements to make predictions based on continuous metrology information. RNNs may be trained using a training dataset to generate a fixed number of outputs (e.g., to determine substrate processing rates or modify a substrate process recipe). One type of RNN that may be used is a long short-term memory (LSTM) neural network. For RNNs, CAP depth is potentially unlimited as a signal may propagate multiple times through a layer.

Neural network training may be achieved via supervised learning, which includes feeding a training dataset with labeled inputs through the network, observing its outputs, defining an error (by measuring the difference between outputs and label values), and using techniques like deep gradient descent and backpropagation to tune network weights across all layers and nodes to minimize error. In many applications, repeating this process across numerous labeled inputs in the training dataset yields a network that may produce correct output when presented with new, different inputs.

A training dataset may contain hundreds, thousands, tens of thousands, or hundreds of thousands or more sensor data and/or process result data (e.g., metrology data such as one or more thickness profiles associated with the sensor data).

To effectuate training, processing logic may input the training dataset(s) into one or more untrained machine learning models. Before inputting the first data point, the machine learning model may be initialized. Processing logic trains the untrained machine learning model(s) based on the training dataset(s) to generate one or more trained machine learning models that perform various operations as set forth above. Training may be performed by inputting the sensor data into the machine learning model one at a time.

The machine learning model may process the input to generate an output. An artificial neural network includes an input layer that receives values from a data point. The next layer is called a hidden layer, and nodes at the hidden layer each receive one or more of the input values. Each node contains parameters (e.g., weights) to apply to the input values. Each node applies these parameters within a multivariate function (e.g., a non-linear mathematical transformation) to its input values to produce an output value. The next layer may be another hidden layer or an output layer. In either case, the nodes at the next layer receive the output values from the nodes at the previous layer, and each node applies weights to those values and then generates its own output value. This may be performed at each layer. A final layer is the output layer, where there is one node for each class, prediction, or output that the machine learning model may produce. Accordingly, the output may include one or more predictions or inferences.

Processing logic determines an error (e.g., a classification error) by comparing the machine learning model's output (e.g., predictions or inferences) with target labels from the input training data. Processing logic adjusts the weights of one or more nodes in the machine learning model based on this error. An error term or delta may be determined for each node in the artificial neural network. Based on this error, the artificial neural network adjusts parameters (e.g., weights for one or more inputs of a node) for one or more of its nodes. Parameters may be updated via backpropagation, such that nodes at a highest layer are updated first, followed by nodes at the next layer, and so on. An artificial neural network contains multiple layers of nodes, where each layer receives input values from nodes at a previous layer. The parameters for each node include weights associated with the values received from each of the nodes at a previous layer. Accordingly, adjusting the parameters may include adjusting the weights assigned to each of the inputs for one or more nodes at one or more layers in the artificial neural network.

After one or more rounds of training, processing logic may determine whether a stopping criterion has been met. A stopping criterion may include a target level of accuracy, a target number of processed data points (e.g., images) from the training dataset, a target amount of change in parameters over one or more previous data points, or a combination of these or other criteria. In some embodiments, the stopping criterion is met when at least a minimum number of data points have been processed, and a threshold accuracy is achieved. The threshold accuracy may be, for example, 70%, 80%, or 90%. In some embodiments, the stopping criterion is met if the accuracy of the machine learning model has stopped improving. If the stopping criterion has not been met, further training is performed. If the stopping criterion has been met, training may be complete. Once the machine learning model is trained, a reserved portion of the training dataset may be used to test the model.

Once trained machine learning models 690, 692 are generated, they may be stored in predictive server 612 as predictive component 614 or as a component of predictive component 614.

Validation engine 684 may validate trained machine learning models 690, 692 using a corresponding set of features from a validation set generated by training data set generator 672. Once model parameters are optimized, validation may be performed to determine if the model has improved and to assess its current accuracy. Validation engine 684 may determine the accuracy of trained machine learning model 690 based on the corresponding sets of features of the validation set. Validation engine 684 may discard trained machine learning model 690 if its accuracy does not meet a threshold. In some embodiments, selection engine 685 may select trained machine learning model 690 if it has an accuracy that meets a threshold. In some embodiments, selection engine 685 selects trained machine learning model 690 that has the highest accuracy among trained machine learning models 690.

Testing engine 686 may test a trained machine learning model 690 using a corresponding set of features from a testing set generated by training data set generator 672. For example, a first one of trained machine learning models 690, 692, trained using a first set of features from the training set, may be tested using the first set of features from the testing set. Testing engine 686 may determine which of trained machine learning models 690, 692 has the highest accuracy based on the testing sets.

As described in detail below, predictive server 612 includes a predictive component 614 that is capable of providing data indicative of the expected behavior of each sub-system of a processing chamber, and running trained machine learning model 690, 692 on the current sensor data input to obtain one or more outputs. The predictive server 612 may further provide data indicative of the health of the processing chamber sub-system and diagnostics. This will be explained in further detail below.

Client device 620, manufacturing equipment 624, sensors 626, metrology equipment 628, predictive server 612, data store 640, server machine 670, and server machine 680 may be coupled to each other via network 630. In some embodiments, network 630 is a public network that provides client device 620 with access to predictive server 612, data store 640, and other publicly available computing devices. In some embodiments, network 630 is a private network that provides client device 620 access to manufacturing equipment 624, metrology equipment 628, data store 640, and other privately available computing devices. Network 630 may include one or more wide area networks (WANs), local area networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

It should be noted that in some other implementations, the functions of server machines 670 and 680, as well as predictive server 612, may be provided by a fewer number of machines. For example, in some embodiments, server machines 670 and 680 may be integrated into a single machine, while in some other or similar embodiments, server machines 670 and 680, as well as predictive server 612, may be integrated into a single machine.

In general, functions described in one implementation as being performed by server machine 670, server machine 680, and/or predictive server 612 may also be performed on client device 620. In addition, the functionality attributed to a particular component may be performed by different or multiple components operating together.

In embodiments, a “user” may be represented as a single individual. However, other embodiments of the disclosure encompass a “user” as an entity controlled by a plurality of users and/or an automated source. For example, a group of administrators federated as a single entity may be considered a “user.”

FIG. 7 is a flow chart of method 700 for training a machine learning model, according to aspects of the present disclosure. Method 700 is performed by processing logic that may include hardware (circuitry, dedicated logic, etc.), software (such as is run on a general-purpose computer system or a dedicated machine), firmware, or some combination thereof. In one implementation, method 700 may be performed by computer system architecture 600 of FIG. 6. In other or similar implementations, one or more operations of method 700 may be performed by one or more other machines not depicted in the figures. In some aspects, one or more operations of method 700 may be performed by server machine 670, server machine 680, and/or predictive server 612 of FIG. 6.

At operation 710, processing logic initializes a training set T to an empty set (e.g., {}).

At operation 712, processing logic obtains a first set of data including thermal radiation data indicative of an amount of thermal radiation emitted by a prior substrate during a prior process performed with respect to the prior substrate (e.g., a deposition process performed to deposit one or more layers of film on a surface of the prior substrate). For example, the thermal radiation may be emitted from one or more locations of an edge region of the prior substrate.

At operation 714, processing logic obtains a second set of data including substrate bow data indicative of an amount of bow of the prior substrate. In some embodiments, the second set of data is obtained from data store 640.

In some embodiments, at least one of the first set of data or the second set of data is obtained from data store 640 of FIG. 6. In some embodiments, at least one of the first set of data or the second set of data includes historical data associated with one or more prior process settings for the prior process. For example, the historical data may be historical contextual data associated with the prior process. In some embodiments, the one or more prior process settings may include at least one of a prior temperature setting, a prior pressure setting, one or more prior flow rate settings for one or more precursors, or any other setting associated with the process. A prior flow rate setting may refer to a flow rate setting for a precursor at an initial instance of the prior process (e.g., an initial flow rate setting), a flow rate setting for the precursor at a final instance of the prior process (e.g., a final flow rate setting), or a ramping rate for the flow rate of the precursor during the process.

At operation 716, processing logic generates first training data based on the first set of data. At operation 718, processing logic generates second training data based on the second set of data. At operation 720, processing logic generates an association between the first training data and the second training data. This association (e.g., mapping) refers to the first training data (which includes or is based on the thermal radiation data) being associated with (e.g., mapped to) the second training data (which includes or is based on the substrate bow data).

At operation 722, processing logic adds the mapping to the training set T. At operation 724, processing logic determines whether the training set T includes enough training data to train a machine learning model. It should be noted that in some implementations, the sufficiency of training set T may be determined based on the number of elements in the training set. In other implementations, the sufficiency may be determined based on one or more other criteria (e.g., a measure of diversity of the training examples) in addition to, or instead of, the number of input/output mappings. If the training set does not include enough training data to train the machine learning model, method 700 returns to operation 712. If the training set T includes enough training data to train the machine learning model, method 700 continues to operation 726.

At operation 728, processing logic provides the training set T to train a machine learning model. In some embodiments, the training set T is provided to training engine 682 of FIG. 6 to perform the training. In the case of a neural network, for example, input values of a given input/output mapping are input to the neural network, and output values of the input/output mapping are stored in the output nodes of the neural network. The connection weights in the neural network are then adjusted in accordance with a learning algorithm (e.g., backpropagation, etc.), and the procedure is repeated for the other input/output mappings in the training set T.

In some embodiments, the processing logic may perform outlier detection methods to remove anomalies from the training set T prior to training the machine learning model. Outlier detection methods may include techniques that identify values that differ significantly from most of the training data. These values may be generated from errors, noise, etc.

After operation 726, the machine learning model may be trained to receive thermal radiation data corresponding to one or more locations of a substrate (e.g., one or more locations of an edge region of the substrate) and output a value indicative of an amount of bow of the substrate For simplicity of explanation, the methods are depicted and described herein as a series of acts. However, acts in accordance with this disclosure may occur in various orders and/or concurrently, and with other acts not presented and described herein. Furthermore, not all illustrated acts may be performed to implement the methods in accordance with the disclosed subject matter. In addition, those skilled in the art will understand and appreciate that the methods could alternatively be represented as a series of interrelated states via a state diagram or events. Additionally, it should be appreciated that the methods disclosed in this specification are capable of being stored on an article of manufacture to facilitate transporting and transferring such methods to computing devices. The term article of manufacture, as used herein, is intended to encompass a computer program accessible from any computer-readable device or storage media.

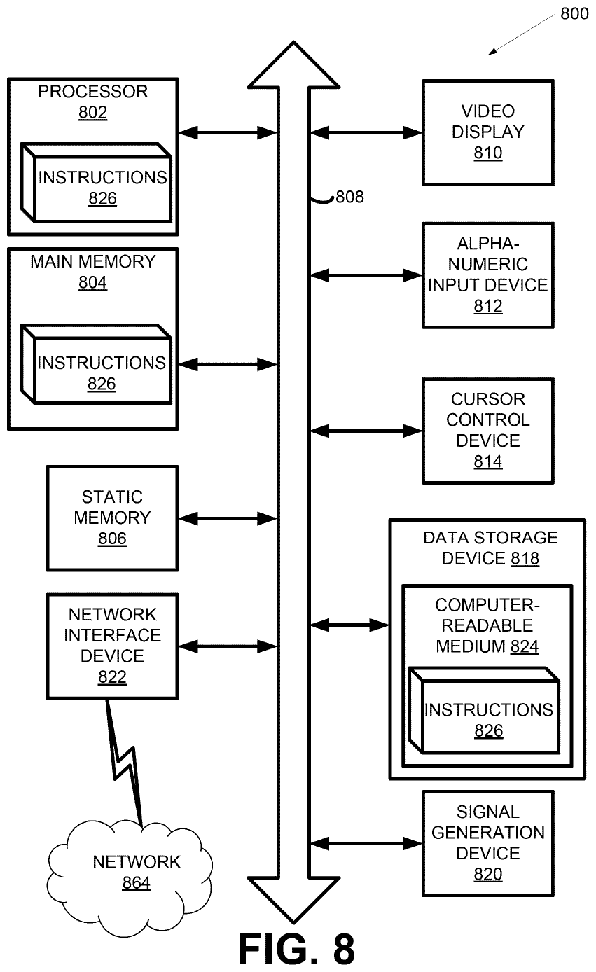

FIG. 8 depicts a diagrammatic representation of machine in the example form of computing device 800 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet computer, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In embodiments, computing device 800 may correspond to controller 166 of FIG. 1 and/or bow monitoring system 460 of FIG. 4.

The computing device 800 includes a processing device 802, a main memory 804 (e.g., read-only memory (ROM), flash memory, dynamic random access memory (DRAM) such as synchronous DRAM (SDRAM), etc.), a static memory 806 (e.g., flash memory, static random access memory (SRAM), etc.), and a secondary memory (e.g., a data storage device 818), which communicate with each other via a bus 808.

Processing device 802 may represent one or more general-purpose processors such as a microprocessor, central processing unit, or the like. More particularly, processing device 802 may be a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. Processing device 802 may also be one or more special-purpose processing devices such as an application-specific integrated circuit (ASIC), a field-programmable gate array (FPGA), a digital signal processor (DSP), a network processor, or the like. Processing device 802 may also be or include a system on a chip (SoC), a programmable logic controller (PLC), or another type of processing device. Processing device 802 is configured to execute the processing logic for performing operations discussed herein.

The computing device 800 may further include network interface device 822 for communicating with network 864. The computing device 800 also may include video display unit 810 (e.g., a liquid crystal display (LCD) or a cathode ray tube (CRT)), alphanumeric input device 812 (e.g., a keyboard), cursor control device 814 (e.g., a mouse), and signal generation device 820 (e.g., a speaker).

Data storage device 818 may include non-transitory computer-readable storage medium 824 on which is stored one or more sets of instructions 826 embodying any one or more of the methodologies or functions described herein. A non-transitory storage medium refers to a storage medium other than a carrier wave. The instructions 826 may also reside, completely or at least partially, within main memory 804 and/or within processing device 802 during execution thereof by computer device 800, main memory 804 and processing device 802 also constituting computer-readable storage media.

While the non-transitory computer-readable storage medium 824 is shown in an example embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium capable of storing or encoding a set of instructions for execution by the machine and that cause the machine to perform any one or more of the methodologies of the present disclosure. The term “computer-readable storage medium” shall accordingly be taken to include, but not be limited to, solid-state memories, and optical and magnetic media.

The preceding description sets forth numerous specific details, such as examples of specific systems, components, methods, and so forth, to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format to avoid unnecessarily obscuring the present disclosure. Thus, the specific details set forth are merely exemplary. Implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in some embodiments,” “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of operations of each method may be altered. Certain operations may be performed in an inverse order, or at least in part, concurrently with other operations. In another embodiment, instructions or sub-operations of distinct operations may be performed in an intermittent and/or alternating manner.

It is understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A system comprising:
a memory; and
at least one processing device, operatively coupled with the memory, to:
initiate a process with respect to a substrate;
obtain thermal radiation data corresponding to one or more locations on the substrate;
determine an amount of bow of the substrate based on the thermal radiation data; and
cause at least one corrective action to be performed based on the amount of bow of the substrate, the at least one corrective action comprising at least one of:
cause an alert to be generated; or
cause at least one process parameter of the process to be changed.

2. The system of claim 1, wherein the process comprises an epitaxial deposition process.

3. The system of claim 1, wherein the at least one processing device is further to:
determine whether the amount of bow of the substrate satisfies a threshold condition; and
in response to determining that the amount of bow of the substrate satisfies the threshold condition, cause the at least one corrective action to be performed.

4. The system of claim 1, wherein the at least one processing device is further to input the thermal radiation data into a machine learning model trained to perform at least one of:
determine the amount of bow; or
cause the at least one corrective action to be performed.

5. The system of claim 1, wherein the thermal radiation data is obtained based on a plurality of thermal radiation signals, and wherein each thermal radiation signal of the plurality of thermal radiation signals corresponds to a respective location on the substrate.

6. The system of claim 5, wherein the thermal radiation data is obtained based on an average of the plurality of thermal radiation signals.

7. The system of claim 1, wherein the thermal radiation data comprises a change in intensity of thermal radiation between a first radiation signal received from a given location of the substrate at an initial state of the process, and a second radiation signal received from the given location of substrate at a current state of the process.

8. The system of claim 1, wherein the thermal radiation data is obtained during the process.

9. The system of claim 1, wherein the at least one process parameter comprises at least one of: a temperature, a pressure, a process duration, or a flow.

10. A method comprising:
initiating, by at least one processing device, a process with respect to a substrate;
obtaining, by the at least one processing device during the process, thermal radiation data corresponding to one or more locations on the substrate;
determining, by the at least one processing device, whether the thermal radiation data satisfies a threshold condition; and
in response to determining that the thermal radiation data satisfies the threshold condition, causing, by the at least one processing device, at least one corrective action to be performed to address bow of the substrate.

11. The method of claim 10, wherein the process comprises a deposition process.

12. The method of claim 11, wherein the deposition process is an epitaxial deposition process.

13. The method of claim 12, wherein the epitaxial deposition process is superlattice epitaxy.

14. The method of claim 10, wherein the thermal radiation data is obtained based on an intensity of at least one thermal radiation signal.

15. The method of claim 14, wherein the at least one thermal radiation signal comprises a plurality of thermal radiation signals, and wherein the thermal radiation data is obtained based on an intensity of each thermal radiation signal of the plurality of thermal radiation signals.

16. The method of claim 15, wherein the thermal radiation data is obtained based on an average intensity of the plurality of thermal radiation signals.

17. The method of claim 10, wherein causing the at least one corrective action to be performed comprises causing an alert to be generated.

18. The method of claim 10, wherein causing the at least one corrective action to be performed comprises causing at least one process parameter of the process to be changed.

19. The method of claim 18, wherein the at least one process parameter comprises at least one of: a temperature, a pressure, a process duration, or a flow.

20. A system comprising:
a processing chamber comprising a substrate support assembly;
a thermal radiation detector located above the substrate support assembly; and
a bow monitoring system comprising at least one processing device, operatively coupled with a memory, to:
initiate a process with respect to a substrate on the substrate support assembly;
obtain, from the thermal radiation detector during the process, thermal radiation data based on an intensity of a plurality of thermal radiation signals, wherein each thermal radiation signal of the plurality of thermal radiation signals corresponds to a respective location of a plurality of locations with respect to an edge region of the substrate, and wherein the thermal radiation detector is configured to rotate to measure thermal radiation at each location of the plurality of locations; and
cause at least one corrective action to be performed based on an amount of bow of the substrate corresponding to the thermal radiation data, the at least one corrective action comprising at least one of:
cause an alert to be generated; or
cause at least one process parameter of the process to be changed.
